(19) United States
(12) Patent Application Publication
(10) Pub. No.: US 2026/0353554 A1
(43) Pub. Date: Nov. 5, 2026

(54) PRINTED CIRCUIT BOARD AND SECONDARY BATTERY INCLUDING THE SAME

(71) Applicant: SAMSUNG SDI CO., LTD., Yongin-si (KR)

(72) Inventors: KANGMIN LEE, Yongin-si (KR); JIYUN CHOI, Yongin-si (KR)

(21) Appl. No.: 19/663,449

(22) Filed: Apr. 30, 2026

(30) Foreign Application Priority Data
May 2, 2025 (KR) 10-2025-0058368

(51) Int. Cl. H05K 1/02; H01M 10/42; H01M 10/48; H01M 50/574; H05K 1/14

(52) U.S. Cl. CPC H05K 1/0296; H01M 10/425; H01M 10/486; H01M 50/574; H05K 1/142; H01M 2010/4271; H05K 2201/09027

(57) ABSTRACT

A printed circuit board, including a substrate, a photo solder resist layer on at least a portion of one surface of the substrate, and an insulating layer covering at least one region of the substrate, wherein the substrate includes an exposed region that is not overlapped by the photo solder resist layer and the insulating layer, and wherein a soldering region is in the exposed region.

### CROSS-REFERENCE TO RELATED APPLICATION

This application is based on and claims priority under 35 U.S.C. § 119 to Korean Patent Application No. 10-2025-0058368, filed on May 2, 2025, in the Korean Intellectual Property Office, the disclosure of which is incorporated by reference herein in its entirety.

### BACKGROUND

### 1. Field

The present disclosure relates to a printed circuit board and a secondary battery including the same.

### 2. Description of the Related Art

A secondary battery is a battery that is capable of charging and discharging, unlike a primary battery which cannot be recharged. Low-capacity battery cells are used in portable small electronic devices such as smartphones, feature phones, notebook computers, digital cameras, and camcorders, while high-capacity battery cells are widely used as power sources for driving motors and as power storage batteries, such as in hybrid vehicles and electric vehicles. Such battery cells include an electrode assembly including a positive electrode and a negative electrode, a case accommodating the electrode assembly, and electrode terminals connected to the electrode assembly.

### SUMMARY

Embodiments include a printed circuit board, including a substrate, a photo solder resist layer on at least a portion of one surface of the substrate, and an insulating layer covering at least one region of the substrate, wherein the substrate includes an exposed region that is not overlapped by the photo solder resist layer and the insulating layer, and wherein a soldering region is in the exposed region.

The substrate may include a first circuit board, a second circuit board on one side of the first circuit board, the second circuit board being electrically connected to the first circuit board, and a third circuit board on another side of the first circuit board opposite to the one side on which the second circuit board is electrically connected, the third circuit board being electrically connected to the first circuit board, wherein the soldering region includes a first soldering region in a region of the second circuit board and a second soldering region in a region of the third circuit board.

The first circuit board may have greater rigidity than that of either the second circuit board or the third circuit board.

At least one region of the first circuit board may have an electronic component thereon.

The second circuit board may have a terminal portion at another end thereof, opposite to one end thereof electrically connected to the first circuit board, and the first soldering region may be between the one end connected to the first circuit board and the other end at the terminal portion.

The third circuit board may have a terminal portion at another end thereof, opposite to one end thereof electrically connected to the first circuit board, and the second soldering region may be between the one end connected to the first circuit board and the other end at the terminal portion.

The soldering region may have a plurality of solder pads therein.

The plurality of solder pads may be spaced apart from each other and in two rows along a longitudinal direction of the second circuit board or the third circuit board.

Each of the plurality of solder pads may have a circular shape, and a diameter of each of the plurality of solder pads may vary according to a width direction length of the second or third circuit board, the width direction intersecting a longitudinal direction at the soldering region.

The diameter of the solder pad may follow Equation 1:

[Equation 1]

(x−y−z)/2

(x: width-direction length of the second or third circuit board, y: distance from an outermost edge of the second or third circuit board to a solder pad of the plurality of solder pads nearest thereto, z: distance between adjacent of the plurality of solder pads).

Each of the second circuit board and the third circuit board may include a connection portion that is soldered while overlapping with the first circuit board.

The second circuit board or the third circuit board may further include a bending portion between the connection portion and the soldering region, and the second circuit board or the third circuit board may be foldable at the bending portion such that one surface of the second circuit board or the third circuit board on which the soldering region is faces the first circuit board.

The printed circuit board may further include an insulating tape covering the connection portion.

Embodiments include a secondary battery, including a battery cell, a substrate electrically connected to the battery cell, a photo solder resist layer on at least a portion of one surface of the substrate, and an insulating layer covering at least one region of the substrate, wherein the substrate includes an exposed region that is not overlapped by the photo solder resist layer and the insulating layer, and wherein a soldering region is in the exposed region.

The substrate may further include a first circuit board, a second circuit board disposed on one side of the first circuit board, the second circuit board being electrically connected to the first circuit board, and a third circuit board on another side of the first circuit board, opposite to the one side on which the second circuit board is electrically connected, the third circuit board being electrically connected to the first circuit board, wherein the soldering region includes a first soldering region in a region of the second circuit board and a second soldering region in a region of the third circuit board.

At least one region of the first circuit board may have an electronic component thereon.

The soldering region may include a plurality of solder pads therein.

The plurality of solder pads may be spaced apart from each other and arranged in two rows along a longitudinal direction of the second circuit board or the third circuit board.

Each of the second circuit board and the third circuit board includes a connection portion that is soldered while overlapping with the first circuit board.

The second circuit board or the third circuit board may further include a bending portion located between the connection portion and the soldering region, and the second circuit board or the third circuit board may be foldable at the bending portion such that one surface on which the soldering region is faces the first circuit board.

### BRIEF DESCRIPTION OF THE DRAWINGS

Features will become apparent to those of ordinary skill in the art by describing in detail exemplary embodiments with reference to the attached drawings, in which:

FIG. 1 is a plan view schematically illustrating an example of a printed circuit board according to an embodiment of the present disclosure;

FIG. 2 is a plan view schematically illustrating an example of an opposite surface of the printed circuit board shown in FIG. 1;

FIGS. 3 and 4 are plan views schematically illustrating an example of a second circuit board of the printed circuit board shown in FIG. 1;

FIG. 5 is a cross-sectional view taken along line I-I′ of FIG. 4;

FIGS. 6 and 7 are plan views schematically illustrating an example of a third circuit board of the printed circuit board shown in FIG. 1;

FIG. 8 is a cross-sectional view taken along line II-II′ of FIG. 7;

FIGS. 9 and 10 are views schematically illustrating an example of a folding configuration of the printed circuit board shown in FIG. 1;

FIG. 11 is a perspective view schematically illustrating an example of a secondary battery including the printed circuit board shown in FIG. 1;

FIG. 12 is a plan view schematically illustrating an example of a printed circuit board according to another embodiment of the present disclosure;

FIGS. 13 and 14 are plan views schematically illustrating an example of a fifth circuit board of the printed circuit board shown in FIG. 12;

FIGS. 15 and 16 are views schematically illustrating an example of a folding configuration of the printed circuit board shown in FIG. 12; and

FIG. 17 is a perspective view schematically illustrating an example of a secondary battery including the printed circuit board shown in FIG. 12.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Furthermore, as used herein, “comprise” or “include” and/or “comprising” or “including” specify the presence of stated features, numbers, steps, operations, members, elements, and/or groups thereof, and do not exclude the presence or addition of one or more other features, numbers, operations, members, elements, and/or groups thereof.

In addition, to aid understanding of the disclosure, the accompanying drawings are not drawn to actual scale, and the dimensions of some components may be exaggerated for clarity. Also, the same reference numerals may be assigned to the same components in different embodiments.

Although terms such as first, second, etc. are used to describe various components, these components are not limited by these terms. These terms are used merely to distinguish one component from another component, and unless specifically stated to the contrary, a first component may be a second component.

Throughout the specification, unless specifically stated to the contrary, each component may be singular or plural.

The statement that any configuration is disposed “above (or below)” a component or “on (or under)” a component means not only that the configuration is disposed in contact with the upper surface (or lower surface) of the component, but also that another configuration may be interposed between the component and any configuration disposed on (or under) the component.

Also, when a component is described as being “connected,” “coupled,” or “joined” to another component, it should be understood that the components may be directly connected or joined to each other, but other components may be “interposed” between the components, or the components may be “connected,” “coupled,” or “joined” through other components. Furthermore, when a part is said to be electrically coupled to another part, this includes not only cases where they are directly connected, but also cases where they are connected with other elements interposed therebetween.

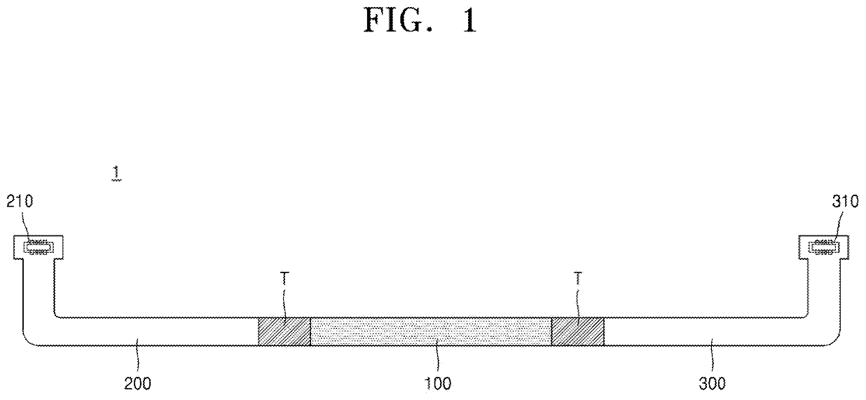

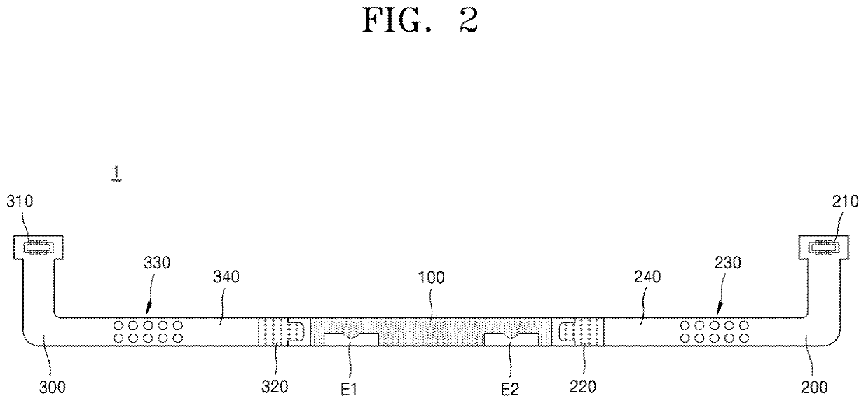

FIG. 1 is a plan view schematically illustrating an example of a printed circuit board according to an embodiment of the present disclosure, and FIG. 2 is a plan view schematically illustrating an example of an opposite surface of the printed circuit board shown in FIG. 1.

Referring to FIGS. 1 and 2, a printed circuit board 1 according to an embodiment of the present disclosure may include: a first circuit board 100; a second circuit board 200 disposed on one side of the first circuit board 100 and electrically connected to the first circuit board 100; and a third circuit board 300 disposed on another side of the first circuit board 100 and electrically connected to the first circuit board 100, and may further include a first soldering region 230 located in a region of the second circuit board 200, and a second of the soldering region 330 located in a region of the third circuit board 300.

The first circuit board 100 may include electrode portions E1, E2 in at least one region thereof, and the electrode portions E1, E2 may be connected to a positive electrode or a negative electrode of a battery cell. For example, the first circuit board 100 may be connected to tabs of the positive and negative electrodes of a battery cell and thereby electrically connected to the battery cell. In this case, charging and discharging currents of the battery cell may flow through the first circuit board 100, which is connected to the positive and negative electrodes, and may flow through an external connection terminal 210 of the second circuit board 200 and an external connection terminal 310 of the third circuit board 300, which are respectively connected to opposite sides of the first circuit board 100.

By allowing the charging and discharging current of the battery cell to pass through the first circuit board 100 and to flow through the external connection terminal 210 of the second circuit board 200 and the external connection terminal 310 of the third circuit board 300, which are respectively connected to opposite sides of the first circuit board 100, the printed circuit board 1 may monitor the charging and discharging voltage, charging and discharging current, and/or temperature of the battery cell and may protect the battery cell from overcharging and overdischarging. In addition, the external connection terminal 210 of the second circuit board 200 and the external connection terminal 310 of the third circuit board 300 may be connected to an external electronic device to charge or discharge the battery cell.

That is, the printed circuit board 1 according to an embodiment of the present disclosure may be connected to an external electronic device through the external connection terminal 210 of the second circuit board 200 and the external connection terminal 310 of the third circuit board 300, and may receive currents of opposite polarities from both directions to charge the battery cell, and may function as a protection circuit module that protects the battery cell from overcharging and overdischarging. In this case, receiving currents of opposite polarities from both directions to charge the battery cell may allow a large amount of current to flow, thereby enabling rapid charging of the battery cell.

Meanwhile, the second circuit board 200 and the third circuit board 300, connected to the first circuit board 100, may respectively include connection portions 220, 320 that are soldered to and overlapped with one region at one end and one region at the other end of the first circuit board 100, and through the connection portions 220, 320, the second circuit board 200 and the third circuit board 300 may be electrically connected to the first circuit board 100.

In an optional embodiment, an insulating tape T may be disposed to insulate the exposed solder of the connection portions 220, 320 of the second circuit board 200 and the third circuit board 300, and the insulating tape T may be disposed to cover the connection portions 220, 320 of the second circuit board 200 and the third circuit board 300.

To perform such protective operations for preventing overcharging, overdischarging, and/or overcurrent in the battery cell, at least one electronic component, such as a plurality of positive temperature coefficient (PTC) devices may be mounted on the first circuit board 100 of the printed circuit board 1.

For example, the first circuit board 100 may be formed as a relatively rigid circuit board, unlike the second and third circuit boards 200, 300, and a plurality of circuit elements may be arranged on the first circuit board 100 to control charging and discharging operations of the battery cell by responding to abnormal conditions such as overheating, overcharging, or overdischarging, while forming a charge/discharge path between the battery cell and the second and third circuit boards 200, 300.

As a specific example, the first circuit board 100 may function as a battery management system (BMS) that monitors status information such as temperature, voltage, and current of the battery cell, detects abnormal conditions, and implements protective actions such as stopping charging or discharging operations. As such, in an embodiment of the present disclosure, the first circuit board 100 may be formed as a relatively rigid circuit board, unlike the second and third circuit boards 200, 300. However, in various embodiments of the present disclosure, the first circuit board 100 may also include a flexible film configuration, similar to the second and third circuit boards 200, 300.

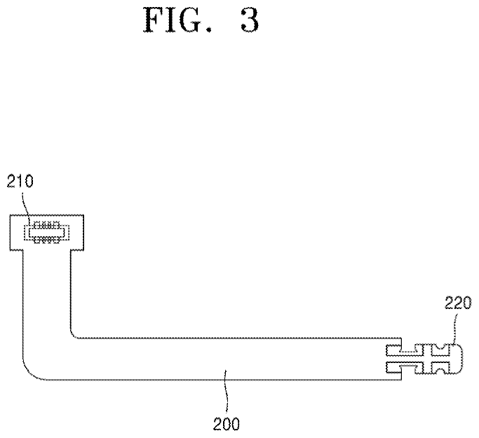

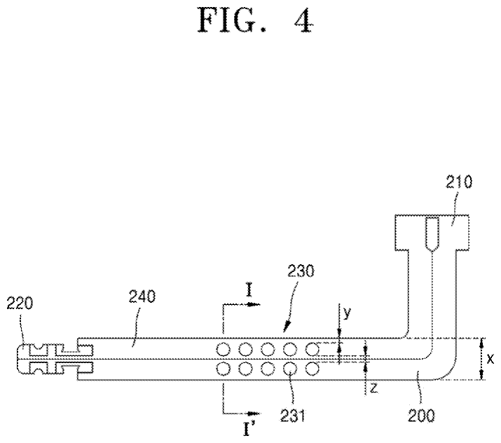

FIGS. 3 and 4 are plan views schematically illustrating an example of the second circuit board of the printed circuit board shown in FIG. 1.

Referring to FIGS. 3 and 4, the second circuit board 200 may have a connection portion 220 disposed at one end, which is electrically connected to the first circuit board 100 through soldering, and may have an external connection terminal 210 disposed at the other end, which is connected to an external electronic device.

The second circuit board 200 may allow a current from an electrode different from that supplying current to the third circuit board 300 to flow; for example, the second circuit board 200 may carry a positive electrode current.

Meanwhile, as higher current flows, heat generation may increase. However, the printed circuit board 1 according to an embodiment of the present disclosure may include a first soldering region 230 on one surface of the second circuit board 200, thereby effectively dissipating the generated heat.

The first soldering region 230 may be located between the external connection terminal 210 and the connection portion 220 on one surface of the second circuit board 200. For example, the first soldering region 230 may include a plurality of solder pads 231, and the plurality of solder pads 231 may be spaced apart from each other and arranged along the longitudinal direction of the second circuit board 200.

In other embodiments, the plurality of solder pads 231 may be spaced apart from each other and arranged in two rows along the longitudinal direction of the second circuit board 200, and may be arranged to have a circular shape.

The diameter of each of the plurality of solder pads 231, which has a circular shape, may vary according to the width-direction length (x) of the second circuit board 200, which intersects the longitudinal direction in which the soldering region is located.

For example, the diameter of the plurality of solder pads 231 may follow Equation 1 below.

[Equation 1]

(x−2y−z)/2

(x: width-direction length of the second circuit board, y: distance between the outermost edge of the second circuit board and the solder pad nearest thereto, z: distance between adjacent solder pads).

Meanwhile, the distance (y) between an outermost edge of the second circuit board 200 and a nearest of the plurality of solder pads 231 to the outermost edge of the second circuit board 200 may need to be spaced apart by 0.4 mm or more. If the distance (y) between the outermost edge of the second circuit board 200 and the nearest of the plurality of solder pads 231 to the outermost edge of the second circuit board 200 is not spaced apart by 0.4 mm or more, lifting defects of the plurality of solder pads 231 may occur.

In addition, the distance (z) between adjacent of the plurality of solder pads 231 may need to be spaced apart by 0.25 mm or more. If the distance (z) between adjacent of the plurality of solder pads 231 is not spaced apart by 0.25 mm or more, a risk of short-circuiting may occur between the plurality of solder pads 231.

That is, by determining the diameter of the plurality of solder pads 231 based on Equation 1, it is possible to prevent potential issues that may arise when the distance (y) from the outermost edge of the second circuit board 200 to the plurality of solder pads 231 nearest thereto, or the distance (z) between adjacent of the plurality of solder pads 231 is too small, while also enabling optimization of the size of the plurality of solder pads 231 to correspond to the width (x) of the second circuit board 200.

Furthermore, by determining the diameter of the plurality of solder pads 231 according to Equation 1, the diameter of the plurality of solder pads 231 may vary according to the width-direction length (x) of the second circuit board 200.

Meanwhile, the second circuit board 200 may include a flexible printed circuit board (FPCB), and the FPCB may have a multilayer structure. For example, the multilayer FPCB may be formed by stacking three or more layers including a base film, a copper layer, a copper plating layer, and a polymer film, thereby forming a fine circuit. In this case, a coverlay region, which is an insulating layer including a PSR layer and a polyimide (PI) film, may be disposed on one surface of the multilayer FPCB.

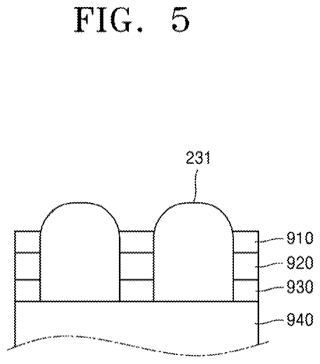

FIG. 5 is a cross-sectional view taken along line I-I′ of FIG. 4.

FIG. 5 shows a partial cross section of a stacked structure disposed on one surface of the second circuit board 200.

The stacked structure formed on one surface of the second circuit board 200 may include a PSR layer 910 disposed on at least a portion of the one surface and an insulating layer 920 covering at least one region of the second circuit board 200, and the second circuit board 200 may include an exposed region that is not overlapped by the PSR layer 910 and the insulating layer 920. In this case, an adhesive layer 930 may be disposed between the insulating layer 920 and a copper layer 940, and the adhesive layer 930 may also be removed together with the insulating layer 920, such that the plurality of solder pads 231 can be disposed in the exposed region formed on the copper layer 940.

In summary, the plurality of solder pads 231 may be disposed in an exposed region formed by removing the PSR layer 910 disposed on one surface of the second circuit board 200, the insulating layer 920 covering at least one region of the second circuit board 200, and the adhesive layer 930, and the plurality of solder pads 231 may be disposed in the exposed region while being in direct contact with the copper layer 940. By arranging the plurality of solder pads 231 in direct contact with the copper layer 940, which is a conductive layer, heat that increases as a high current flows through the copper layer 940 may be directly transferred to the plurality of solder pads 231, and the heat transferred to the plurality of solder pads 231 may be readily dissipated to the outside through the plurality of solder pads 231, which is exposed externally. As a result, by disposing the plurality of solder pads 231 in the exposed region from which the PSR layer 910 and the insulating layer have been removed, the heat dissipation characteristics of the second circuit board 200 may be improved.

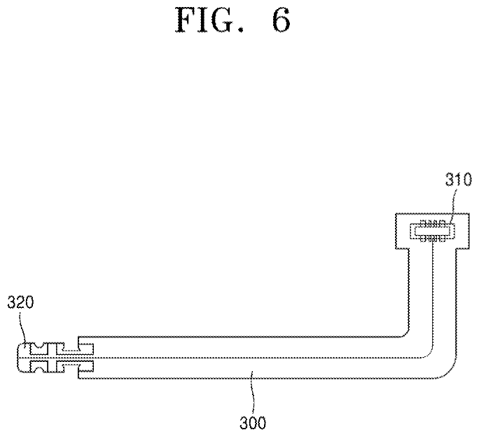

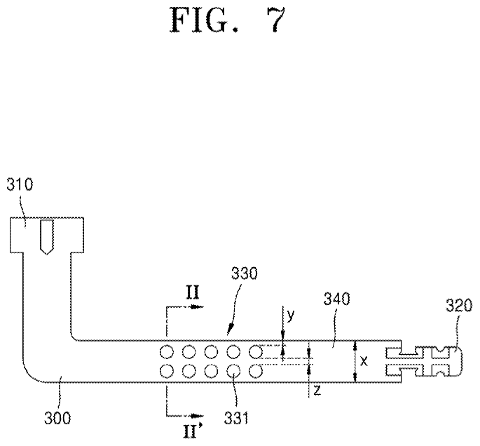

FIGS. 6 and 7 are plan views schematically illustrating an example of the third circuit board of the printed circuit board shown in FIG. 1.

Referring to FIGS. 6 and 7, the third circuit board 300 may have a connection portion 320 disposed at one end, which is electrically connected to the first circuit board 100 through soldering, and may have an external connection terminal 310 disposed at the other end, which is connected to an external electronic device.

The third circuit board 300 may allow a current from an electrode that is different from that of the current supplied to the second circuit board 200 from the external electronic device to flow; for example, the third circuit board 300 may carry a negative electrode current.

Meanwhile, as higher current flows, heat generation may increase. However, the printed circuit board 1 according to an embodiment of the present disclosure may include a soldering region 330 on one surface of the third circuit board 300, thereby effectively dissipating the heat.

The soldering region 330 may be located between the external connection terminal 310 and the connection portion 320 on one surface of the third circuit board 300. For example, the soldering region 330 may include a plurality of solder pads 331, and the plurality of solder pads 331 may be spaced apart from each other and disposed along the longitudinal direction of the third circuit board 300.

In other embodiments, the plurality of solder pads 331 may be spaced apart from each other and arranged in two rows along the longitudinal direction of the third circuit board 300, and may be arranged to have a circular shape.

The diameter of one of the plurality of solder pads 331, which has a circular shape, may vary according to the width-direction length (x) of the third circuit board 300, which intersects the longitudinal direction of the third circuit board 300 in which the soldering region is located.

For example, the diameter of one of the plurality of solder pads 331 may follow Equation 2 below.

[Equation 2]

(x−2y−z)/2

(x: width-direction length of the third circuit board, y: distance between the outermost edge of the third circuit board and the solder pad nearest thereto, z: distance between adjacent solder pads).

Meanwhile, the distance (y) between the outermost edge of the third circuit board 300 and the solder pad 331 nearest to the outermost edge of the third circuit board 300 may need to be spaced apart by 0.4 mm or more. If the distance (y) between the outermost edge of the third circuit board 300 and the nearest solder pad 331 to the outermost edge of the third circuit board 300 is not spaced apart by 0.4 mm or more, lifting defects of the solder pad 331 may occur.

In addition, the distance (z) between adjacent solder pads 331 may need to be spaced apart by 0.23 mm or more. If the distance (z) between adjacent solder pads 331 is not spaced apart by 0.23 mm or more, a risk of short-circuiting may occur between the solder pads 331.

That is, by determining the diameter of the plurality of solder pads 231 based on Equation 2, it is possible to prevent potential issues that may arise when the distance (y) from the outermost edge of the third circuit board 300 to the solder pad 331 nearest thereto, or the distance (z) between adjacent solder pads 331 is too small, while also enabling optimization of the size of the solder pad 331 to correspond to the width (x) of the third circuit board 300.

Furthermore, by determining the diameter of the solder pad 331 according to Equation 2, the diameter of the solder pad 331 may vary according to the width-direction length (x) of the third circuit board 300.

Meanwhile, the third circuit board 300 may include a flexible printed circuit board (FPCB), and the FPCB may have a multilayer structure. For example, the multilayer FPCB may be formed by stacking three or more layers including a base film, a copper layer, a copper plating layer, and a polymer film, thereby forming a fine circuit. In this case, a coverlay region, which is an insulating layer including a PSR layer and a polyimide (PI) film, may be disposed on one surface of the multilayer FPCB.

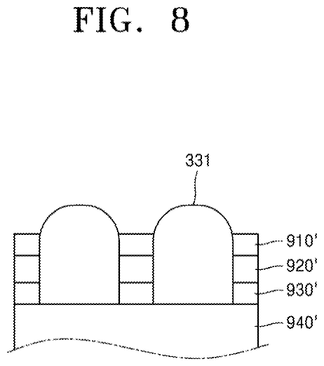

FIG. 8 is a cross-sectional view taken along line II-II′ of FIG. 7.

FIG. 8 shows a partial cross section of a stacked structure disposed on one surface of the third circuit board 300.

The stacked structure formed on one surface of the third circuit board 300 may include a PSR layer 910′ disposed on at least a portion of the one surface of the third circuit board 300 and an insulating layer 920′ covering at least one region of the third circuit board 300, and the third circuit board 300 may include an exposed region that is not overlapped by the PSR layer 910′ and the insulating layer 920′. In this case, an adhesive layer 930′ may be disposed between the insulating layer 920′ and a copper layer 940′, and the adhesive layer 930′ may also be removed together with the insulating layer 920′, such that the solder pad 331 can be disposed in the exposed region formed on the copper layer 940′.

In summary, the solder pad 331 may be disposed in an exposed region formed by removing the PSR layer 910′ disposed on one surface of the third circuit board 300, the insulating layer 920′ covering at least one region of the third circuit board 300, and the adhesive layer 930′, and the solder pad 331 may be disposed in the exposed region while being in direct contact with the copper layer 940′. By arranging the solder pad 331 in direct contact with the copper layer 940′, which is a conductive layer, heat that increases as a high current flows through the copper layer 940′ may be directly transferred to the solder pad 331, and the heat transferred to the solder pad 331 may be readily dissipated to the outside through the solder pad 331, which is exposed externally. As a result, by disposing the solder pad 331 in the exposed region from which the PSR layer 910′ and the insulating layer 920′ have been removed, the heat dissipation characteristics of the third circuit board 300 may be improved.

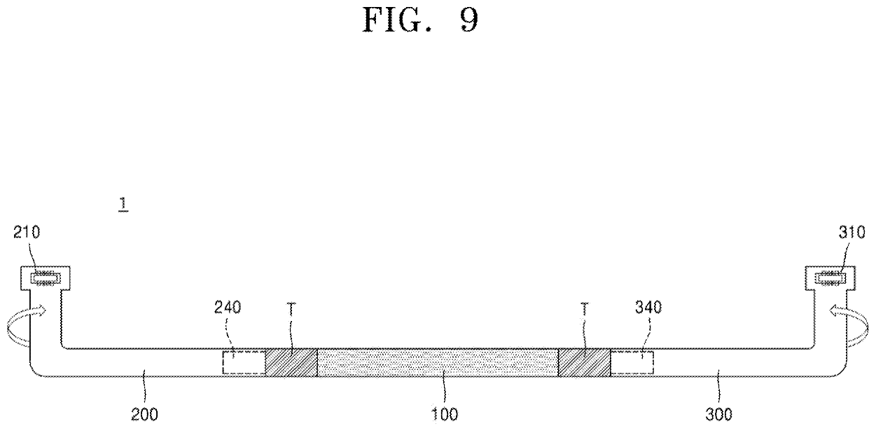

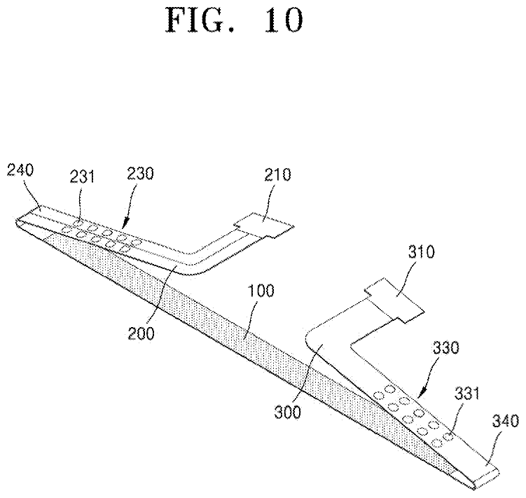

FIGS. 9 and 10 are schematic views illustrating an example of a folding configuration of the printed circuit board shown in FIG. 1.

Referring to FIGS. 9 and 10, in a printed circuit board 1 according to an embodiment of the present disclosure, the second circuit board 200 or the third circuit board 300 may be moved toward the first circuit board 100 by a bending portion 240 or 340.

As a specific example, the second circuit board 200 may further include a bending portion 240 located between the connection portion 220 and the first soldering region 230, wherein the second circuit board 200 is foldable at the bending portion 240 such that one surface of the second circuit board 200 on which the first soldering region 230 is located faces the first circuit board 100. The third circuit board 300 may also further include a bending portion 340 located between the connection portion 320 and the soldering region 330, wherein the third circuit board 300 is foldable at the bending portion 340 such that one surface of the third circuit board 300 on which the soldering region 330 is located faces the first circuit board 100.

As a result, in the printed circuit board 1 according to an embodiment of the present disclosure, the second circuit board 200 and the third circuit board 300 may be folded at their respective bending portions 240 and 340, such that one surface of the second circuit board 200 on which the first soldering region 230 is formed and one surface of the third circuit board 300 on which the soldering region 330 is formed are folded toward the first circuit board 100, resulting in a folded configuration. In this case, by folding such that the surfaces of the second and third circuit boards 200, 300 on which the soldering regions 230, 330 are formed face the first circuit board 100, it is possible to prevent conduction issues that may arise upon external exposure of the soldering regions 230, 330.

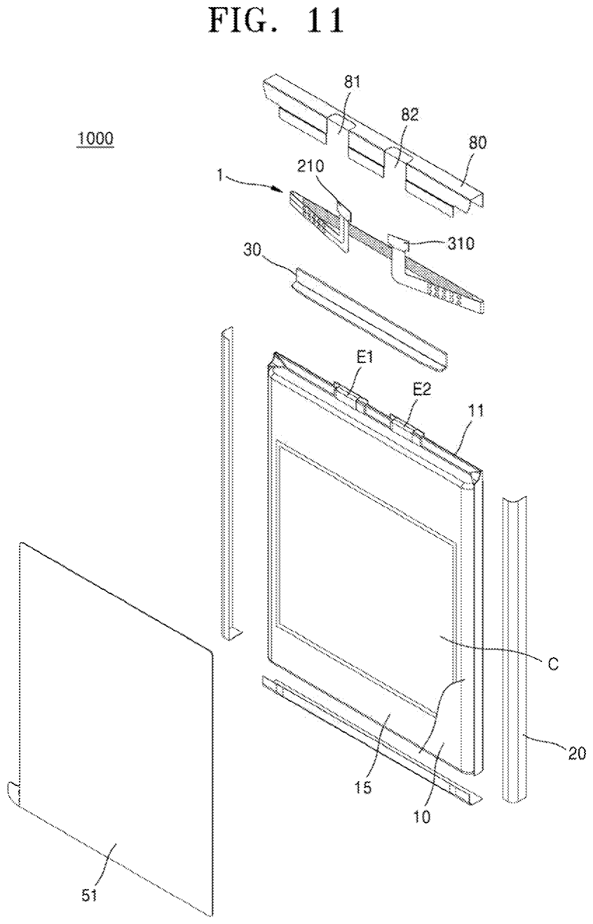

FIG. 11 is a perspective view schematically illustrating an example of a secondary battery including the printed circuit board shown in FIG. 1.

Referring to FIG. 11, an insulating tape 20 may be attached along at least a portion of the perimeter of the battery cell C, and an insulating adhesive tape 30 may be placed between a terrace portion 11 of the battery cell C and the printed circuit board 1 to mediate an insulating connection among the first circuit board 100, the second circuit board 200, and the third circuit board 300. In this case, the printed circuit board 1 may be arranged such that the second circuit board 200 and the third circuit board 300 are folded toward the first circuit board 100. Then, an insulating member 80 may be attached on the printed circuit board 1 to insulate and protect the first circuit board 100, the second circuit board 200, and the third circuit board 300 from the surrounding environment. In this case, the insulating member 80 may have openings 81, 82 formed therein corresponding to the external connection terminals 210 and 310 of the second and third circuit boards 200 and 300, respectively, which are folded toward the first circuit board 100. The external connection terminals 210 and 310 of the second and third circuit boards 200, 300 may be exposed through the openings 81, 82, respectively, and connected to an external electronic device.

In addition, the secondary battery may further include a label sheet 51 attached to the battery cell C, and the label sheet attached to the battery cell C may serve to insulate and protect the battery cell C, and to provide a display region for showing product information such as the model name or manufacturer of the battery cell C.

The battery cell C may include an electrode assembly 10 and an exterior material 15 that seals the electrode assembly 10 together with an electrolyte (not shown) and includes a terrace portion 11 from which first and second electrodes E1, E2, electrically connected to the electrode assembly 10, are drawn out. As described below, the printed circuit board 1 that is electrically connected to the first electrode E1 and the second electrode E2 may be disposed on the terrace portion 11.

The electrode assembly 10 may be wound with a separator, which is an insulator, between a positive electrode and a negative electrode.

The positive and negative electrodes may be wound with the separator interposed therebetween. However, the electrode assembly 10 may, in some embodiments, have a stacked structure in which multiple sheets of positive and negative electrodes are alternately stacked with separators interposed therebetween.

The first electrode E1 and the second electrode E2 may correspond to either a positive or a negative electrode, and the positive and negative electrodes may include a coated portion, which is a region of a thin metal foil current collector coated with an active material, and a non-coated portion, which is a region where no active material is coated.

As a result, a secondary battery according to another embodiment of the present disclosure may exhibit improved heat dissipation characteristics by removing a portion of the layers in a region of a multilayer printed circuit board and soldering the region from which the layers have been partially removed.

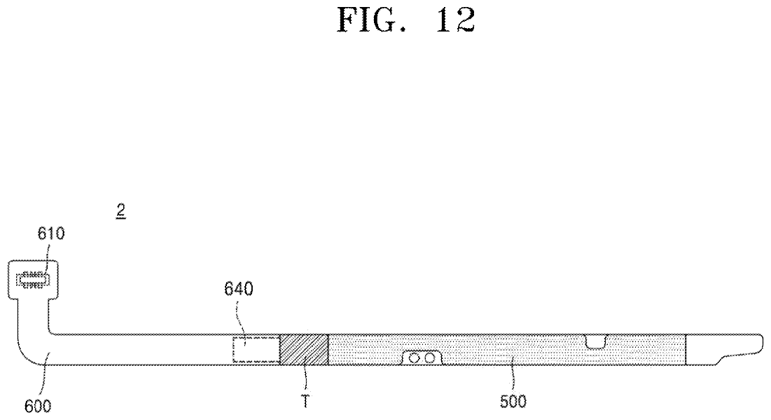

FIG. 12 is a plan view schematically illustrating an example of a printed circuit board according to another embodiment of the present disclosure.

Referring to FIG. 12, a printed circuit board 2 according to another embodiment of the present disclosure may include a fourth circuit board 500 and a fifth circuit board 600 that is disposed on one side of the fourth circuit board 500 and electrically connected to the fourth circuit board 500.

The fourth circuit board 500 may include electrode portions E1, E2 in at least one region thereof, and the electrode portions E1, E2 may be connected to a positive electrode or a negative electrode of a battery cell. For example, the fourth circuit board 500 may be connected to the tabs of the positive and negative electrodes of the battery cell and thereby electrically connected to the battery cell. In this case, the charging and discharging currents of the battery cell may flow through the fourth circuit board 500, which is connected to the positive and negative electrodes, and flow through an external connection terminal 610 of the fifth circuit board 600 connected to one side of the fourth circuit board 500.

Accordingly, the charging and discharging currents of the battery cell may flow through the fourth circuit board 500 and be connected to the external connection terminal 610 of the fifth circuit board 600 connected to one side of the fourth circuit board 500, such that the printed circuit board 2 may monitor charging and discharging voltage, charging and discharging current, and/or temperature of the battery cell and protect the battery cell from overcharging and overdischarging. In addition, the external connection terminal 610 of the fifth circuit board 600 may be connected to an external electronic device to charge or discharge the battery cell.

That is, the printed circuit board 2 according to an embodiment of the present disclosure may be connected to an external electronic device through the external connection terminal 610 of the fifth circuit board 600, thereby functioning as a protection circuit module that protects the battery cell from overcharging and overdischarging.

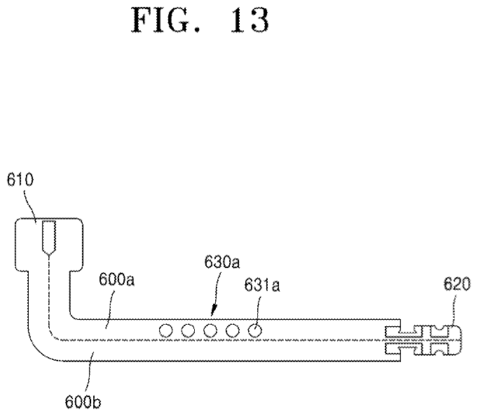

Meanwhile, the fifth circuit board 600 connected to the fourth circuit board 500 may include a connection portion 620 (see FIG. 13) that is soldered while overlapping (e.g., soldered and overlaps) with one region of one end of the fourth circuit board 500, and through this connection portion 620, the fifth circuit board 600 may be electrically connected to the fourth circuit board 500.

In other embodiments, an insulating tape T may be disposed over the connection portion 620 of the fifth circuit board 600 to insulate the exposed solders, and this insulating tape T may be arranged to cover the connection portion 620 of the fifth circuit board 600.

To perform such protection operations for preventing overcharging, overdischarging, and/or overcurrent of the battery cell, at least one electronic component, such as a positive temperature coefficient (PTC) device, may be mounted on the fourth circuit board 500 of the printed circuit board 2.

For example, the fourth circuit board 500 may be formed as a relatively rigid circuit board, unlike the fifth circuit board 600, and a plurality of circuit elements may be disposed on the fourth circuit board 500 to control charging and discharging operations of the battery cell in response to abnormal conditions such as overheating, overcharging, or overdischarging of the battery cell, while forming a charging and discharging path between the battery cell and the fifth circuit board 600.

As a specific example, the fourth circuit board 500 may monitor the status information of the battery cell, such as temperature, voltage, and current, detect abnormal conditions, and function as a battery management system (BMS) that performs protective measures such as stopping charging or discharging. As such, in one embodiment of the present disclosure, the fourth circuit board 500 may be formed as a relatively rigid circuit board, unlike the fifth circuit board 600, but in various embodiments of the present disclosure, the fourth circuit board 500 may also include a flexible film structure similar to that of the fifth circuit board 600.

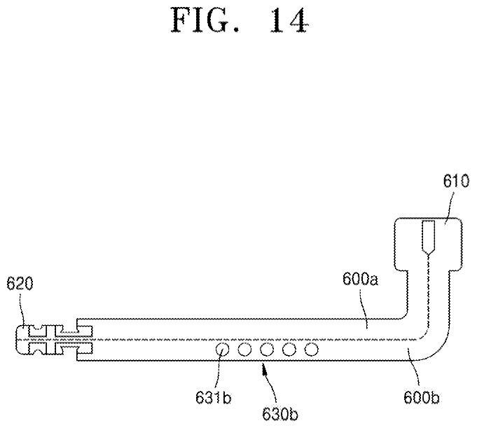

FIGS. 13 and 14 are plan views schematically illustrating an example of the fifth circuit board of the printed circuit board shown in FIG. 12.

Referring to FIGS. 13 and 14, the fifth circuit board 600 may include a connection portion 620 located at one end, which is electrically connected to the fourth circuit board 500 through soldering, and the external connection terminal 610 located at the other end, which is connected to an external electronic device. The fifth circuit board 600 may further include a first current path portion 600a and a second current path portion 600b, and the first current path portion 600a and the second current path portion 600b may carry currents from different electrodes.

Meanwhile, the printed circuit board 2 may increase heat generation as a higher current flows. However, the printed circuit board 2 according to an embodiment of the present disclosure may include a third soldering region 630a on one surface of the fifth circuit board 600 and a fourth soldering region 630b on the other surface of the fifth circuit board 600, thereby effectively dissipating the generated heat.

The third soldering region 630a, located on one surface of the fifth circuit board 600, may be disposed between the external connection terminal 610 and the connection portion 620, and may carry a current from an electrode different from that of the fourth soldering region 630b. In addition, the third soldering region 630a may include a plurality of solder pads 631a, and the plurality of solder pads 631a may be spaced apart from each other and disposed in the first current path portion 600a along the longitudinal direction of the fifth circuit board 600.

The fourth soldering region 630b, located on the other surface of the fifth circuit board 600, may be disposed between the external connection terminal 610 and the connection portion 620, and may carry a current from an electrode different from that of the third soldering region 630a. In addition, the fourth soldering region 630b may include a plurality of solder pads 631b, and the plurality of solder pads 631b may be spaced apart from each other and arranged along the longitudinal direction of the fifth circuit board 600 within the second current path portion 600b.

Meanwhile, the fifth circuit board 600 may include a flexible printed circuit board (FPCB), and the FPCB may have a multi-layer structure. For example, the multilayer FPCB may be formed by stacking three or more layers including a base film, a copper layer, a copper plating layer, and a polymer film, thereby forming fine circuits. In this case, a coverlay region, which is an insulating layer including a PSR layer and a polyimide (PI) film, may be disposed on one surface of the multilayer FPCB.

The stacked structure formed on one surface of the first current path portion 600a of the fifth circuit board 600 may include a PSR layer disposed on at least a portion of one surface of the fifth circuit board 600, and an insulating layer covering at least one region of the fifth circuit board 600, and the fifth circuit board 600 may include an exposed region that is not overlapped by the PSR layer and the insulating layer. An adhesive layer may be disposed between the insulating layer and the copper layer, and this adhesive layer may also be removed together with the insulating layer such that a solder pad 631a may be disposed in the exposed region formed on the copper layer.

In summary, the solder pad 631a may be disposed in an exposed region formed by removing the PSR layer disposed on one surface of the fifth circuit board 600, the insulating layer covering at least one region of the fifth circuit board 600, and the adhesive layer, and the solder pad 631a may be disposed in the exposed region while being in direct contact with the copper layer. By arranging the solder pad 631a in direct contact with the copper layer, which is a conductive layer, heat that increases as a high current flows through the copper layer may be directly transferred to the solder pad 631a, and the heat transferred to the solder pad 631a may be readily dissipated to the outside through the solder pad 631a, which is exposed externally. As a result, by disposing the solder pad 631a in the exposed region from which the PSR layer and the insulating layer have been removed, the heat dissipation characteristics of the fifth circuit board 600 may be improved.

The stacked structure formed on the other surface of the second current path portion 600b of the fifth circuit board 600 may include a PSR layer disposed on at least a portion of the other surface of the fifth circuit board 600, and an insulating layer covering at least one region of the fifth circuit board 600, and the fifth circuit board 600 may include an exposed region that is not overlapped by the PSR layer and the insulating layer. An adhesive layer may be disposed between the insulating layer and the copper layer, and this adhesive layer may also be removed together with the insulating layer such that a solder pad 631b may be disposed in the exposed region formed on the copper layer.

In summary, the solder pad 631b may be disposed in an exposed region formed by removing the PSR layer disposed on the other surface of the fifth circuit board 600, the insulating layer covering at least one region of the fifth circuit board 600, and the adhesive layer, and the solder pad 631b may be disposed in the exposed region while being in direct contact with the copper layer. By arranging the solder pad 631b in direct contact with the copper layer, which is a conductive layer, heat that increases as a high current flows through the copper layer may be directly transferred to the solder pad 631b, and the heat transferred to the solder pad 631b may be readily dissipated to the outside through the solder pad 631b, which is exposed externally. As a result, by disposing the solder pad 631b in the exposed region from which the PSR layer and the insulating layer have been removed, the heat dissipation characteristics of the fifth circuit board 600 may be improved.

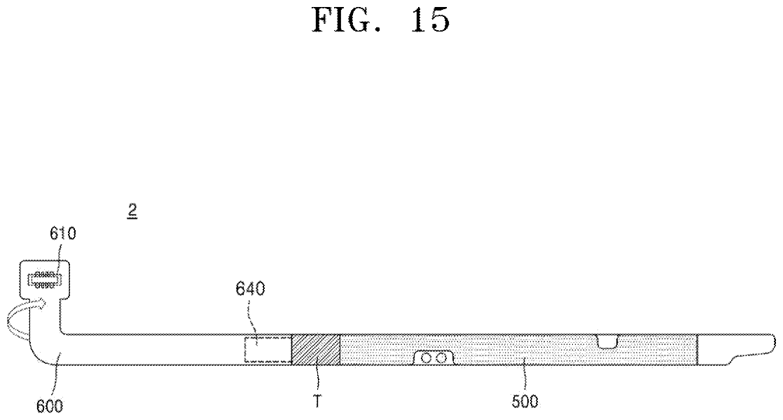

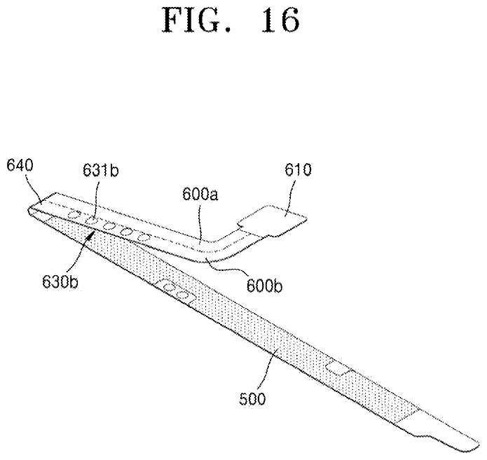

FIGS. 15 and 16 are views schematically illustrating an example of a folding configuration of the printed circuit board 2 of FIG. 9.

Referring to FIGS. 15 and 16, in a printed circuit board 2 according to an embodiment of the present disclosure, the fifth circuit board 600 may be folded toward the fourth circuit board 500 at a bending portion 640.

In a specific example, the fifth circuit board 600 may further include a bending portion 640 located between the connection portion 620 and the third soldering region 630a, and the fifth circuit board 600 may be folded at the bending portion 640 such that one surface on which the third soldering region 630a is located faces the fourth circuit board 500.

In other embodiments, the first current path portion 600a on one surface of the fifth circuit board 600 where the third soldering region 630a is located may carry a positive electrode current, and the second current path portion 600b of the fifth circuit board 600 where the fourth soldering region 630b is located may carry a negative electrode current. In this case, the fifth circuit board 600 may be folded at the bending portion 640 such that the surface on which the third soldering region 630a is located faces the fourth circuit board 500, and such that the fourth soldering region 630b of the second current path portion 600b, which carries the negative electrode current, is directed away from the fourth circuit board 500 (i.e., toward the outside). This configuration helps prevent conduction issues during the subsequent battery cell assembly process, where the assembly-facing surface may serve as a ground (GND) electrode, by ensuring that the region with potential contact—the fourth soldering region 630b of the second current path portion 600b—is the one carrying the negative electrode current.

As a result, in the printed circuit board 2 according to an embodiment of the present disclosure, the fifth circuit board 600 may be folded at the bending portion 640 located in the fifth circuit board 600 such that the surface on which the third soldering region 630a is formed is folded toward the fourth circuit board 500, resulting in a folded configuration. In this case, by folding such that the surface on which the third soldering region 630a is formed faces the fourth circuit board 500, the other surface of the fifth circuit board 600 on which the fourth soldering region 630b is formed may face outward, thereby preventing conduction issues with the assembly-facing surface, which may serve as a ground (GND) electrode.

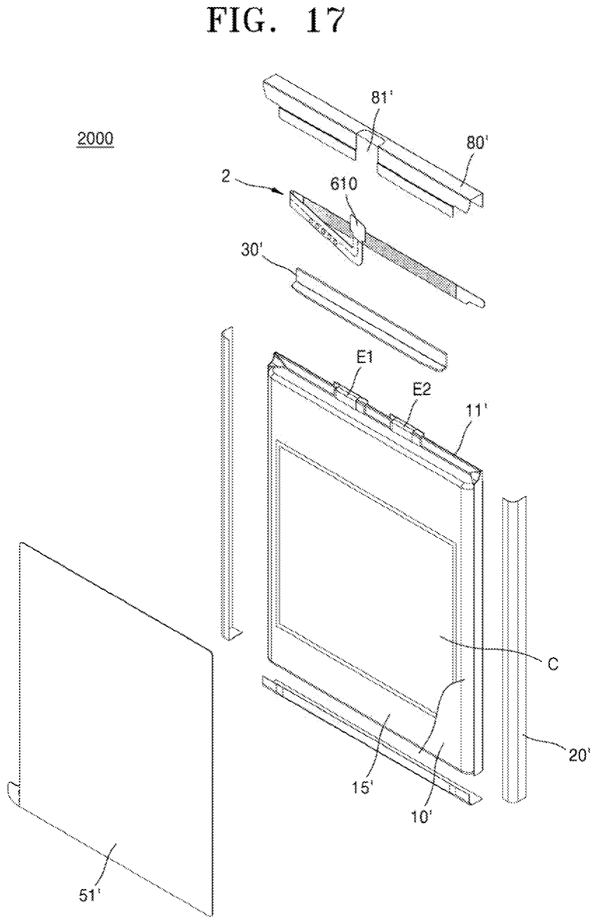

FIG. 17 is a perspective view schematically illustrating an example of a secondary battery including the printed circuit board shown in FIG. 9.

Referring to FIG. 17, an insulating tape 20′ may be attached along the perimeter of the battery cell C, and an insulating adhesive tape 30′ may be interposed between a terrace portion 11′ of the battery cell C and the printed circuit board 2 to mediate an insulating connection between the fourth circuit board 500 and the fifth circuit board 600. In this case, the printed circuit board 2 may be configured such that the fifth circuit board 600 is folded toward the fourth circuit board 500. In addition, an insulating member 80′ may be attached to the printed circuit board 2 to insulate and protect the fourth circuit board 500 and the fifth circuit board 600 from the surrounding environment. In this case, the insulating member 80′ may have an opening 81′ formed therein corresponding to the external connection terminal 610 of the fifth circuit board 600 that is folded toward the fourth circuit board 500, and the external connection terminal 610 of the fifth circuit board 600 may be exposed through the opening 81′ and connected to an external electronic device.

In addition, the secondary battery may further include a label sheet 51′ attached to the battery cell C, and the label sheet may be attached to the battery cell C to insulate and protect the battery cell C, and may provide a display region for displaying product information such as the model name or manufacturer of the battery cell C.

The battery cell C may include an electrode assembly 10′ and an exterior material 15′ that seals the electrode assembly 10′ together with an electrolyte (not shown), and includes a terrace portion 11′ from which the first and second electrodes E1, E2, electrically connected to the electrode assembly 10′, are drawn out. As is described below, a printed circuit board 2 that is electrically connected to the first electrode E1 and the second electrode E2 may be disposed on the terrace portion 11′.

The electrode assembly 10′ may be wound with a separator, which is an insulator, interposed between a positive electrode and a negative electrode.

The positive electrode and the negative electrode may be wound with a separator, which is an insulator, interposed therebetween. However, the electrode assembly 10 may also have a stacked structure in which multiple sheets of positive and negative electrodes are alternately stacked with a separator interposed therebetween.

The first electrode E1 or the second electrode E2 may correspond to either a positive electrode or a negative electrode, respectively, and the positive electrode and the negative electrode may include a coated portion, which is a region on a thin metal foil current collector where an active material is applied, and a non-coated portion, which is a region where no active material is applied.

As a result, a secondary battery according to another embodiment of the present disclosure may exhibit improved heat dissipation characteristics by removing a portion of the layers in a region of a multilayer printed circuit board and soldering the region from which the layers have been partially removed.

According to embodiments of the present disclosure, a secondary battery may exhibit improved heat dissipation characteristics by removing some of the layers from a selected region of a multilayer printed circuit board and then soldering that region where the layers were removed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A printed circuit board, comprising:
a substrate;
a photo solder resist layer on at least a portion of one surface of the substrate; and
an insulating layer covering at least one region of the substrate,
wherein the substrate includes an exposed region that is not overlapped by the photo solder resist layer and the insulating layer, and
wherein a soldering region is in the exposed region.

2. The printed circuit board as claimed in claim 1, wherein the substrate includes:
a first circuit board;
a second circuit board on one side of the first circuit board, the second circuit board being electrically connected to the first circuit board; and
a third circuit board on another side of the first circuit board opposite to the one side on which the second circuit board is electrically connected, the third circuit board being electrically connected to the first circuit board,
wherein the soldering region includes a first soldering region in a region of the second circuit board and a second soldering region in a region of the third circuit board.

3. The printed circuit board as claimed in claim 2, wherein the first circuit board has greater rigidity than that of either the second circuit board or the third circuit board.

4. The printed circuit board as claimed in claim 2, wherein at least one region of the first circuit board has an electronic component thereon.

5. The printed circuit board as claimed in claim 2, wherein:
the second circuit board has a terminal portion at another end thereof, opposite to one end thereof electrically connected to the first circuit board, and
the first soldering region is between the one end connected to the first circuit board and the another end at the terminal portion.

6. The printed circuit board as claimed in claim 2, wherein:
the third circuit board has a terminal portion at another end thereof, opposite to one end thereof electrically connected to the first circuit board, and
the second soldering region is between the one end connected to the first circuit board and the another end at the terminal portion.

7. The printed circuit board as claimed in claim 2, wherein the soldering region has a plurality of solder pads therein.

8. The printed circuit board as claimed in claim 7, wherein the plurality of solder pads are spaced apart from each other and in two rows along a longitudinal direction of the second circuit board or the third circuit board.

9. The printed circuit board as claimed in claim 8,
wherein each of the plurality of solder pads has a circular shape, and
wherein a diameter of each of the plurality of solder pads varies according to a width direction length of the second or third circuit board, the width direction intersecting a longitudinal direction at the soldering region.

10. The printed circuit board as claimed in claim 9, wherein the diameter of the solder pad follows Equation 1:
[Equation 1]
(x−y−z)/2
(x: width-direction length of the second or third circuit board, y: distance from an outermost edge of the second or third circuit board to a solder pad of the plurality of solder pads nearest thereto, z: distance between adjacent of the plurality of solder pads).

11. The printed circuit board as claimed in claim 2, wherein each of the second circuit board and the third circuit board includes a connection portion that is soldered while overlapping with the first circuit board.

12. The printed circuit board as claimed in claim 11, wherein:
the second circuit board or the third circuit board further includes a bending portion between the connection portion and the soldering region, and
the second circuit board or the third circuit board is foldable at the bending portion such that one surface of the second circuit board or the third circuit board on which the soldering region is faces the first circuit board.

13. The printed circuit board as claimed in claim 11, wherein the printed circuit board further includes an insulating tape covering the connection portion.

14. A secondary battery, comprising:
a battery cell;
a substrate electrically connected to the battery cell;
a photo solder resist layer on at least a portion of one surface of the substrate; and
an insulating layer covering at least one region of the substrate,
wherein the substrate includes an exposed region that is not overlapped by the photo solder resist layer and the insulating layer, and
wherein a soldering region is in the exposed region.

15. The secondary battery as claimed in claim 14, wherein the substrate further includes:
a first circuit board;
a second circuit board disposed on one side of the first circuit board, the second circuit board being electrically connected to the first circuit board; and
a third circuit board on another side of the first circuit board, opposite to the one side on which the second circuit board is electrically connected, the third circuit board being electrically connected to the first circuit board,
wherein the soldering region includes a first soldering region in a region of the second circuit board and a second soldering region in a region of the third circuit board.

16. The secondary battery as claimed in claim 15, wherein at least one region of the first circuit board has an electronic component thereon.

17. The secondary battery as claimed in claim 15, wherein the soldering region includes a plurality of solder pads therein.

18. The secondary battery as claimed in claim 17, wherein the plurality of solder pads are spaced apart from each other and arranged in two rows along a longitudinal direction of the second circuit board or the third circuit board.

19. The secondary battery as claimed in claim 18, wherein each of the second circuit board and the third circuit board includes a connection portion that is soldered while overlapping with the first circuit board.

20. The secondary battery as claimed in claim 19, wherein:
the second circuit board or the third circuit board further includes a bending portion located between the connection portion and the soldering region, and
the second circuit board or the third circuit board is foldable at the bending portion such that one surface on which the soldering region is faces the first circuit board.
